(19) United States
(12) Patent Application Publication
(10) Pub. No.: US 2008/0246148 A1
(43) Pub. Date: Oct. 9, 2008

(54) Electrical Interconnect Structures Having Carbon Nanotubes Therein and Methods of Forming Same

(75) Inventors: Seokjun Won, Seoul (KR); Hokyu Kang, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/972,192

(22) Filed: Jan. 10, 2008

(30) Foreign Application Priority Data
Jan. 12, 2007 (KR) 2007-3836

(51) Int. Cl. H01L 23/52

(52) U.S. Cl. 257/746; 257/E23.141

(57) ABSTRACT

Integrated circuit devices include electrically conductive interconnects containing carbon nanotubes. An electrical interconnect includes a first metal region. A first electrically conductive barrier layer is provided on an upper surface of the first metal region and a second metal region is provided on the first electrically conductive barrier layer. The first electrically conductive barrier layer includes a material that inhibits out-diffusion of the first metal from the first metal region and the second metal region includes a catalytic metal therein. An electrically insulating layer having an opening therein is provided on the second metal region. A plurality of carbon nanotubes are provided as a vertical electrical interconnect in the opening.

### REFERENCE TO PRIORITY APPLICATION

This application claims priority under 35 USC § 119 to Korean Application Serial No. 10-2007-0003836, filed Jan. 12, 2007, the disclosure of which is hereby incorporated herein by reference.

### FIELD OF THE INVENTION

The present invention relates to integrated circuit devices and methods of forming integrated circuit devices and, more particularly, to semiconductor interconnect structures and methods of forming semiconductor interconnect structures.

### BACKGROUND OF THE INVENTION

Integrated circuit devices having highly integrated semiconductor devices therein typically utilize vertical interconnect structures to electrically connect vertically separated conductive lines and semiconductor device structures and regions together. However, as the integration density of semiconductor devices within an integrated circuit has increased, the linewidths and cross-sectional widths of conductive lines and vertical interconnect structures has typically decreased. This decrease in the dimensions of the conductive lines and vertical interconnect structures has increased a need for interconnect materials having lower resistivities. To address this increasing need, interconnect structures have been developed that include highly conductive carbon nanotube structures. One example of a conventional interconnect structure containing a carbon nanotube is disclosed in U.S. Pat. No. 7,247,897 to Choi et al., entitled “Method of Forming a Conductive Line for a Semiconductor Device using a Carbon Nanotube and Semiconductor Device Manufactured using the Method,” the disclosure of which is hereby incorporated herein by reference.

Other conventional interconnect structures containing carbon nanotubes are disclosed in U.S. Patent Publ. Nos. 2004/0182600 and 2006/0071334 to Kawabata et al. and 2006/0071344 to Nihei. Integrated circuit devices containing multi-walled carbon nanotube vias are also disclosed in an article by Mizuhisa Nihei et al., entitled “Carbon Nanotube Vias for Future LSI Interconnects,” Proceedings of the IEEE International Interconnect Technology Conference 2004, pp. 251-253, and an article by Mizuhisa Nihei et al., entitled “Low-resistance Multi-walled Carbon Nanotube Vias with Parallel Channel Conduction of Inner Shells,” Proceedings of the IEEE International Interconnect Technology Conference 2005, Jun. 6-8, pp. 234-236.

### SUMMARY OF THE INVENTION

Integrated circuit devices according to embodiments of the present invention include electrically conductive interconnects containing carbon nanotubes. According to some of these embodiments, an electrical interconnect includes a first metal region having at least a first metal therein, on an integrated circuit substrate. A first electrically conductive barrier layer is provided on an upper surface of the first metal region and a second metal region is provided on the first electrically conductive barrier layer. The first electrically conductive barrier layer includes a material that inhibits out-diffusion of the first metal from the first metal region and the second metal region includes a catalytic metal therein.

According to additional aspects of these embodiments, an electrically insulating layer is provided on the second metal region. This electrically insulating layer has an opening therein that exposes a portion of the second metal region. A plurality of carbon nanotubes are provided as a vertical electrical interconnect. These carbon nanotubes, which extend in the opening, are electrically coupled to the first metal region by the exposed portion of the second metal region and the first electrically conductive barrier layer. According to additional aspects of these embodiments, the first metal may be copper and the electrically conductive barrier layer may include at least one of cobalt alloys, nickel alloys, palladium and indium and combinations thereof. The catalytic metal may also be a metal selected from a group consisting of iron, nickel, cobalt, tungsten, yttrium, palladium and platinum.

According to additional embodiments of the present invention, a second electrically conductive barrier layer may be provided on the plurality of carbon nanotubes. The second electrically conductive barrier layer may include a metal selected from a group consisting of tantalum, tantalum nitride, tungsten, and tungsten nitride. To complete the electrically conductive interconnect, a copper damascene pattern may be provided on the second electrically conductive barrier layer.

According to still further embodiments of the present invention, an electrically conductive capping layer is provided between the second metal region and the electrically insulating layer. The electrically conductive capping layer includes a material that inhibits out-diffusion of oxygen from the electrically insulating layer to the second metal region. The electrically conductive capping layer may have an opening therein that is aligned with the opening in the electrically insulating layer. In particular, the electrically conductive capping layer may contact an upper surface of the second metal region and include a metal selected from a group consisting of cobalt alloys, nickel alloys, palladium and indium and combinations thereof. More particularly, the metal may be selected from a group consisting of phosphorus-doped cobalt alloys, boron-doped cobalt alloys, phosphorus-doped nickel alloys, boron-doped nickel alloys, palladium and indium and combinations thereof.

An integrated circuit device according to an additional embodiment of the invention includes a semiconductor substrate and a first interlayer insulating layer on the semiconductor substrate. The first interlayer insulating layer has a recess therein. A first copper pattern is provided in the recess. In addition, a first electrically conductive barrier layer is provided, which lines a bottom and sidewalls of the recess so that the first electrically conductive barrier layer extends between the first copper pattern and the first interlayer insulating layer. The first electrically conductive barrier layer includes a material that inhibits out-diffusion of copper from the first copper pattern. The first electrically conductive barrier layer may include a metal selected from a group consisting of phosphorus-doped cobalt alloys, boron-doped cobalt alloys, phosphorus-doped nickel alloys, boron-doped nickel alloys, palladium and indium and combinations thereof.

A second electrically conductive barrier layer is also provided on an upper surface of the first copper pattern. The second electrically conductive barrier layer includes a material that inhibits out-diffusion of copper from the first copper pattern. A catalytic metal layer is provided on the second electrically conductive barrier layer and a second interlayer insulating layer is provided on the catalytic metal layer. The catalytic metal layer may include at least one of iron, nickel and cobalt and combinations thereof. The second interlayer insulating layer has an opening therein that exposes a portion of the catalytic metal layer. A plurality of carbon nanotubes are provided in the opening. The nanotubes are electrically coupled to the first copper pattern by the exposed portion of the catalytic metal layer and the second electrically conductive barrier layer. The second electrically conductive barrier layer may include a metal selected from a group consisting of phosphorus-doped cobalt alloys, boron-doped cobalt alloys, phosphorus-doped nickel alloys, boron-doped nickel alloys, palladium and indium and combinations thereof.

A capping layer is also provided, which extends between the catalytic metal layer and the second interlayer insulating layer. The capping layer includes a metal selected from a group consisting of phosphorus-doped cobalt alloys, boron-doped cobalt alloys, phosphorus-doped nickel alloys, boron-doped nickel alloys, palladium and indium and combinations thereof. An integrated circuit device according to an additional embodiment of the present invention includes a semiconductor substrate and a first interlayer insulating layer on the semiconductor substrate. The first interlayer insulating layer has a recess therein and a copper pattern is formed in the recess in the first interlayer insulating layer. An electrically conductive barrier layer is provided on an upper surface of the copper pattern. This electrically conductive barrier layer includes a metal selected from a group consisting of phosphorus-doped cobalt alloys, boron-doped cobalt alloys, phosphorus-doped nickel alloys, boron-doped nickel alloys, palladium and indium and combinations thereof. A catalytic metal layer is provided on the electrically conductive barrier layer and an electrically conductive capping layer is provided on the catalytic metal layer. The electrically conductive capping layer has an upper surface that is coplanar with an upper surface of the first interlayer insulating layer. The capping layer may include a metal selected from a group consisting of phosphorus-doped cobalt alloys, boron-doped cobalt alloys, phosphorus-doped nickel alloys, boron-doped nickel alloys, palladium and indium and combinations thereof. A second interlayer insulating layer is also provided on the first interlayer insulating layer and on the capping layer. The second interlayer insulating layer has an opening therein that is aligned with an opening in the electrically conductive capping layer. A plurality of carbon nanotubes are provided, which extend through the openings in the second interlayer insulating layer and the electrically conductive capping layer. These carbon nanotubes contact the catalytic metal layer. A copper damascene pattern may be provided that extends within a recess in the second interlayer insulating layer and is electrically coupled to the plurality of carbon nanotubes.

Additional embodiments of the present invention include a method of forming an integrated circuit device by forming a first interlayer insulating layer having a recess therein, on a substrate, and then lining the recess with a first electrically conductive barrier layer. The lined recess is filled with a patterned copper layer. The first interlayer insulating layer is then selectively etched back to expose sidewalls of the first electrically conductive barrier layer. A second electrically conductive barrier layer is plated onto the exposed sidewalls of the first electrically conductive barrier layer and onto an upper surface of the patterned copper layer and a catalytic metal layer is plated onto the second electrically conductive barrier layer. A second interlayer insulating layer is then deposited onto the catalytic metal layer. An opening is then formed in the second interlayer insulating layer, which exposes a portion of the catalytic metal layer extending opposite the patterned copper layer. The opening in the second interlayer insulating layer is filled with a plurality of carbon nanotubes that are electrically coupled to the patterned copper layer by the catalytic metal layer and the second electrically conductive barrier layer.

Still further embodiments of the present invention include a method of forming an integrated circuit device by forming a first metal layer on a semiconductor substrate, forming a catalytic metal layer on the first metal layer and forming an interlayer insulating layer on the catalytic metal layer. The catalytic metal layer may be formed using an electroless plating technique. The interlayer insulating layer is patterned to define an opening therein that exposes an upper surface of the catalytic metal layer. A step may then be performed to remove oxygen from the catalytic metal layer using a chemical reduction process. For example, oxygen may be removed from the catalytic metal layer by exposing this layer to hydrogen, such as by exposing the layer to a plasma containing hydrogen. Alternatively, oxygen may be removed from the catalytic metal layer by exposing it to a gas containing hydrogen at a temperature in a range from about 200° C. to about 400° C. A step is also performed to form a plurality of carbon nanotubes in the opening in the patterned interlayer insulating layer. These carbon nanotubes may be covered by a copper damascene pattern.

### BRIEF DESCRIPTION OF THE DRAWINGS

FIGS. 1A-1E are cross-sectional views of intermediate structures that illustrate methods of forming integrated circuit devices according to some embodiments of the present invention.

FIGS. 2A-2E are cross-sectional views of intermediate structures that illustrate methods of forming integrated circuit devices according to some embodiments of the present invention.

FIGS. 3A-3D are cross-sectional views of intermediate structures that illustrate methods of forming integrated circuit devices according to some embodiments of the present invention.

FIGS. 4A-4C are cross-sectional views of intermediate structures that illustrate methods of forming integrated circuit devices according to some embodiments of the present invention.

### DETAILED DESCRIPTION OF PREFERRED EMBODIMENTS

The present invention now will be described more fully herein with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. Like reference numerals refer to like elements throughout.

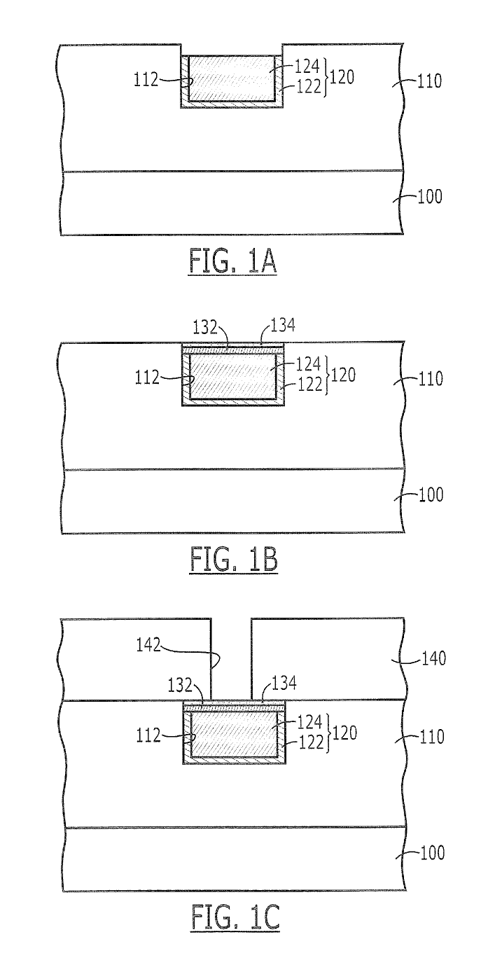

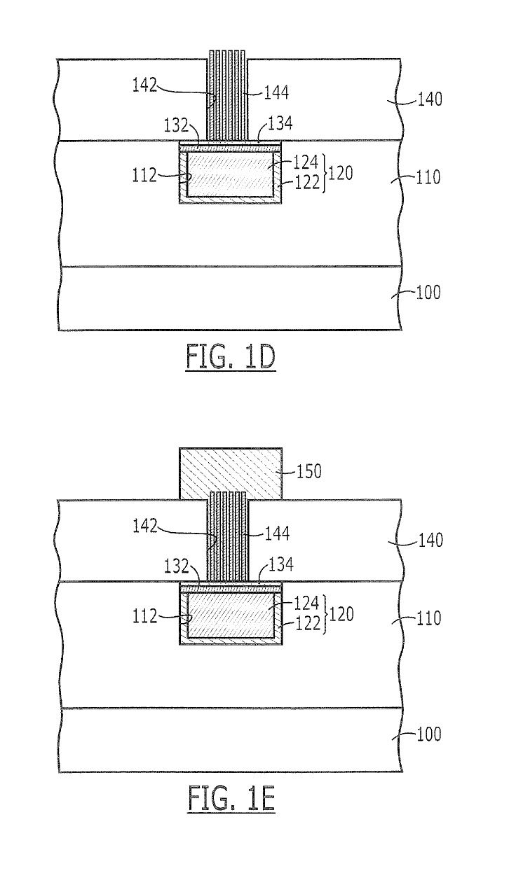

Referring now to FIGS. 1A-1E, methods of forming integrated circuit devices containing electrical interconnects therein include forming a first interlayer insulating layer 110 on a semiconductor substrate 100 and then forming a recess 112 (e.g., trench pattern) in the first interlayer insulating layer 110. This recess 112 may be formed by selectively etching the first interlayer insulating layer 110 using a mask (not shown). As illustrated by FIG. 1A, the first interlayer insulating layer 110 may be formed directly on a primary surface of the semiconductor substrate 100, however, another intervening layer(s) or device structure(s) (not shown) may be formed between the semiconductor substrate 100 and the first interlayer insulating layer 110. The first interlayer insulating layer 110 may be formed of a dielectric material such as silicon dioxide or a low-k dielectric material such as SiCOH, for example.

A bottom and sidewalls of the recess 112 are then lined with a first electrically conductive barrier layer 122. According to some of the embodiments of the present invention, this first electrically conductive barrier layer 122 may be formed as a barrier metal layer containing a metal selected from a group consisting of phosphorus-doped cobalt alloys, boron-doped cobalt alloys, phosphorus-doped nickel alloys, boron-doped nickel alloys, palladium and indium and combinations thereof. A first copper pattern 124 is also formed in the recess 112 using, for example, a copper damascene formation technique that includes planarizing a deposited copper layer for a sufficient duration to define the first copper pattern 124. The step of planarizing a copper layer may include chemically-mechanically polishing the copper layer. As illustrated by FIG. 1A, the first electrically conductive barrier layer 122 extends between the first copper pattern 124 and the first interlayer insulating layer 110. The barrier layer 122 operates to inhibit out-diffusion of copper from the first copper pattern 124 to the surrounding first interlayer insulating layer 110. The barrier layer 122 and the first copper pattern 124 collectively define an electrically conductive pattern 120.

Referring now to FIG. 1B, a second electrically conductive barrier layer 132 is then formed on an upper surface of the first copper pattern 124. This second electrically conductive barrier layer 132, which inhibits out-diffusion of copper from the first copper pattern 124, may be formed selectively on the first copper pattern 124 using an electroless plating technique, for example. The second electrically conductive barrier layer 132 may be formed as a barrier metal layer containing a metal selected from a group consisting of phosphorus-doped cobalt alloys (e.g., Co—W—P alloy), boron-doped cobalt alloys, phosphorus-doped nickel alloys, boron-doped nickel alloys, palladium and indium and combinations thereof. For example, the second electrically conductive barrier layer 132 may be formed as a metal layer selected from a group consisting of: Co—W—P, Co—Sn—P, Co—P, Co—B, Co—Sn—B, Co—W—B, Ni—W—P, Ni—Sn—P, Ni—P, Ni—B, Ni—Sn—B, Ni—W—B, Pd and In. FIG. 1B also illustrates the formation of a catalytic metal layer 134 on the second electrically conductive barrier layer 132 using, for example, an electroless plating technique. According to some embodiments of the invention, the catalytic metal layer 134 may include a material selected from a group consisting of iron, nickel and cobalt and combinations thereof.

Referring now to FIGS. 1C-1D, a second interlayer insulating layer 140 is formed on the first interlayer insulating layer 110 and then patterned to define an opening 142 therein that exposes an upper surface of the catalytic metal layer 134. The second interlayer insulating layer 140 may be formed of a dielectric material such as silicon dioxide or a low-k dielectric material such as SiCOH, for example. The formation of the opening 142 in the second interlayer insulating layer 140 may result in the formation of a native oxide (not shown) on the catalytic metal layer 134, which may inhibit the subsequent formation of carbon nanotubes on the catalytic metal layer 140. This native oxide may be removed by performing a chemical reduction process that includes exposing the second interlayer insulating layer 140 to a hydrogen gas at a temperature in a range between about 200° C. and about 400° C. or exposing the second interlayer insulating layer 140 to a hydrogen plasma at a temperature in a range between about 25° C. and about 450° C.

A plurality of carbon nanotubes 144 may then be formed in the opening 142 using the catalytic metal layer 134 to enhance the rate of nanotube formation within the opening 142. These carbon nanotubes 144 may be formed using conventional techniques, such as chemical vapor deposition, plasma-enhanced chemical vapor deposition, atomic layer deposition and plasma-enhanced atomic layer deposition. As illustrated, the carbon nanotubes 144 are electrically connected to the first copper pattern 124 by the catalytic metal layer 134 and the second electrically conductive barrier layer 132. The vertical interconnect structure illustrated by FIG. 1D may be completed by forming an electrically conductive pattern 150 that extends on the second interlayer insulating layer 140 and electrically contacts the plurality of carbon nanotubes 144, as illustrated by FIG. 1E. Additional materials that may function as a catalytic metal for nanotube formation include tungsten, yttrium, palladium, platinum and gold.

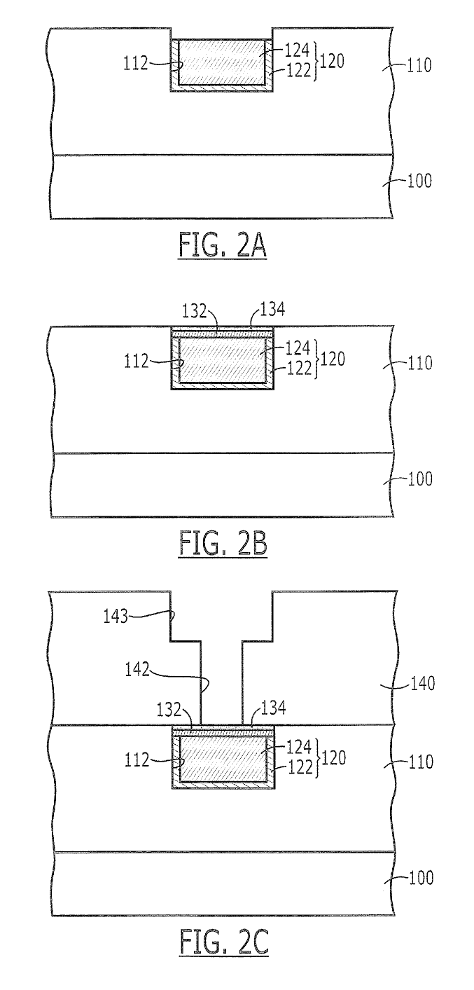

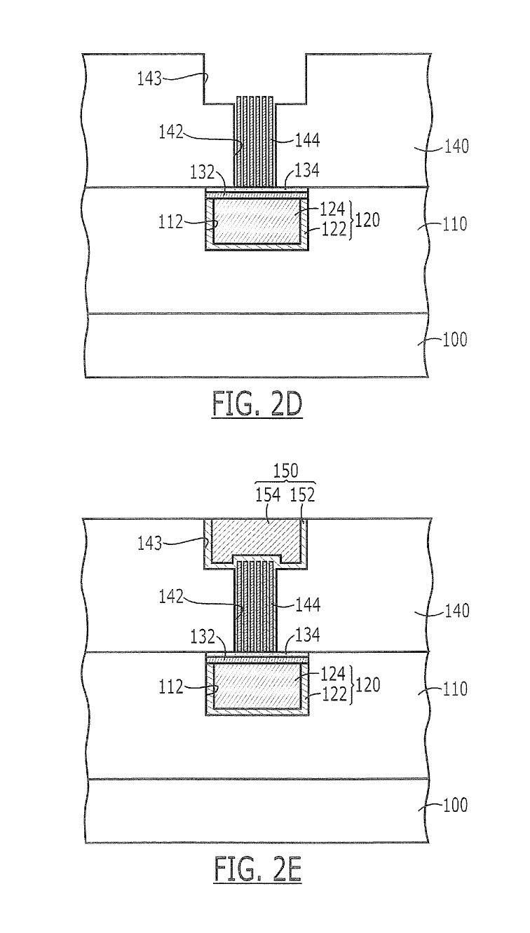

Referring now to FIGS. 2A-2E, methods of forming electrical interconnects according to additional embodiments of the present invention include forming a first interlayer insulating layer 110 on a semiconductor substrate 100 and then forming a recess 112 (e.g., trench pattern) in the first interlayer insulating layer 110 by selectively etching the first interlayer insulating layer 110 using a mask (not shown). As illustrated by FIG. 2A, the first interlayer insulating layer 110 may be formed directly on a primary surface of the semiconductor substrate 100, however, another intervening layer(s) or structure (s) (not shown) may be formed between the semiconductor substrate 100 and the first interlayer insulating layer 110. The first interlayer insulating layer 110 may be formed of a dielectric material such as silicon dioxide or a low-k dielectric material such as SiCOH, for example.

A bottom and sidewalls of the recess 112 are then lined with a first electrically conductive barrier layer 122. According to some of the embodiments of the present invention, this first electrically conductive barrier layer 122 may be formed as a barrier metal layer containing a metal selected from a group consisting of phosphorus-doped cobalt alloys, boron-doped cobalt alloys, phosphorus-doped nickel alloys, boron-doped nickel alloys, palladium and indium and combinations thereof. A first copper pattern 124 is also formed in the recess 112 using, for example, a copper damascene formation technique that includes planarizing a deposited copper layer for a sufficient duration to define the first copper pattern 124. The step of planarizing a copper layer may include chemically-mechanically polishing the copper layer. As illustrated by FIG. 2A, the first electrically conductive barrier layer 122 extends between the first copper pattern 124 and the first interlayer insulating layer 110. The barrier layer 122 operates to inhibit out-diffusion of copper from the first copper pattern 124 to the surrounding first interlayer insulating layer 110. The barrier layer 122 and the first copper pattern 124 collectively define an electrically conductive pattern 120.

Referring now to FIG. 2B, a second electrically conductive barrier layer 132 is then formed on an upper surface of the first copper pattern 124. This second electrically conductive barrier layer 132, which inhibits out-diffusion of copper from the first copper pattern 124, may be formed selectively on the first copper pattern 124 using an electroless plating technique, for example. The second electrically conductive barrier layer 132 may be formed as a barrier metal layer containing a metal selected from a group consisting of phosphorus-doped cobalt alloys (e.g., Co—W—P alloy), boron-doped cobalt alloys, phosphorus-doped nickel alloys, boron-doped nickel alloys, palladium and indium and combinations thereof. For example, the second electrically conductive barrier layer 132 may be formed as a metal layer selected from a group consisting of: Co—W—P, Co—Sn—P, Co—P, Co—B, Co—Sn—B, Co—W—B, Ni—W—P, Ni—Sn—P, Ni—P, Ni—B, Ni—Sn—B, Ni—W—B, Pd and In. FIG. 2B also illustrates the formation of a catalytic metal layer 134 on the second electrically conductive barrier layer 132 using, for example, an electroless plating technique. According to some embodiments of the invention, the catalytic metal layer 134 may include a material selected from a group consisting of iron, nickel and cobalt and combinations thereof, however, other materials that function as a catalytic metal for carbon nanotube formation may also be used.

Referring now to FIGS. 2C-2D, a second interlayer insulating layer 140 is formed on the first interlayer insulating layer 110. The second interlayer insulating layer 140 may be formed of a dielectric material such as silicon dioxide or a low-k dielectric material such as SiCOH, for example. The second interlayer insulating layer 140 may then be selectively patterned using conventional techniques to define a recess 143 therein and also define an opening 142 (e.g., via opening) that extends through the second interlayer insulating layer 140 and exposes an upper surface of the catalytic metal layer 134.

A plurality of carbon nanotubes 144 may then be formed in the opening 142 using the catalytic metal layer 134 to enhance the rate the nanotube formation within the opening 142 (e.g., via opening). These carbon nanotubes 144 may be formed using conventional techniques, such as chemical vapor deposition, plasma-enhanced chemical vapor deposition, atomic layer deposition and plasma-enhanced atomic layer deposition. As illustrated, these carbon nanotubes 144 are electrically connected to the first copper pattern 124 by the catalytic metal layer 134 and the second electrically conductive barrier layer 132.

Referring now to FIG. 2E, a third barrier metal layer 152 may be deposited in the recess 143 to line a bottom and sidewalls thereof and cover the carbon nanotubes 144. A copper pattern 154 may be formed on the third barrier metal layer 152 to yield a copper damascene structure 150 that is electrically coupled to the carbon nanotubes 144. This third barrier metal layer 152 may include a material such as titanium nitride, tantalum, tantalum nitride, tungsten and tungsten nitride, however, other barrier materials may also be used.

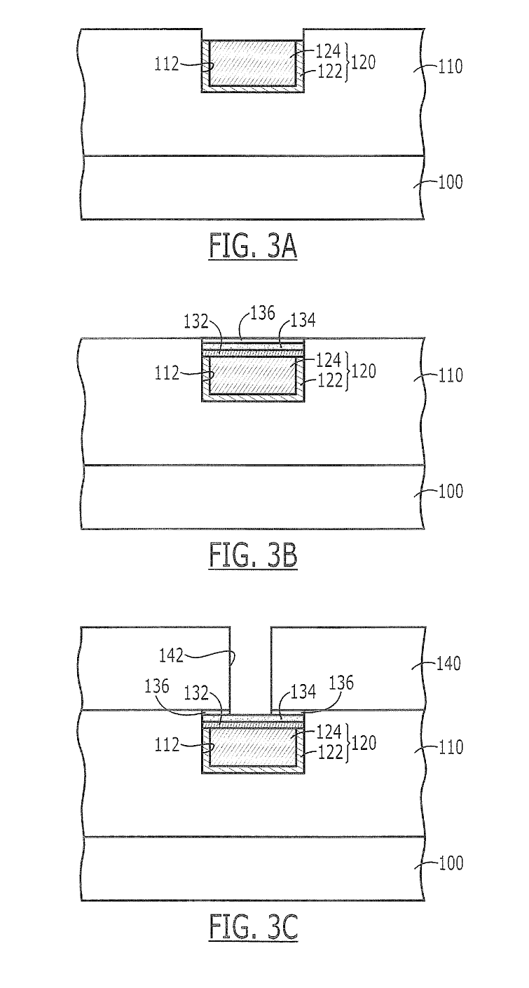

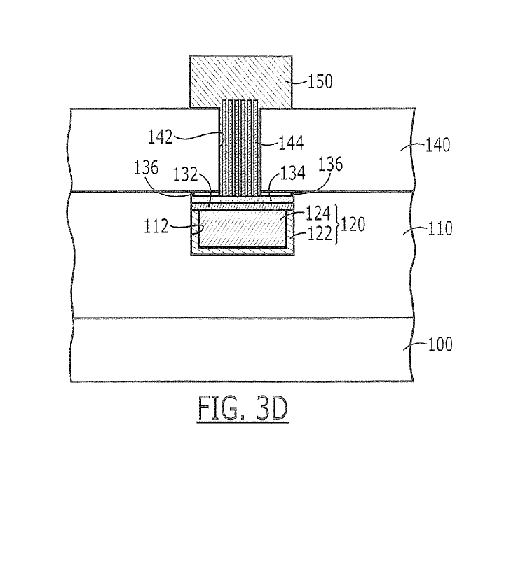

Referring now to FIGS. 3A-3D, methods of forming electrical interconnects according to further embodiments of the present invention include forming a first interlayer insulating layer 110 on a semiconductor substrate 100 and then forming a recess 112 (e.g., trench pattern) in the first interlayer insulating layer 110 by selectively etching the first interlayer insulating layer 110 using a mask (not shown). As illustrated by FIG. 3A, the first interlayer insulating layer 110 may be formed directly on a primary surface of the semiconductor substrate 100, however, another intervening layer(s) and/or structure(s) (not shown) may be formed between the semiconductor substrate 100 and the first interlayer insulating layer 110. The first interlayer insulating layer 110 may be formed of a dielectric material such as silicon dioxide or a low-k dielectric material such as SiCOH, for example.

A bottom and sidewalls of the recess 112 are then lined with a first electrically conductive barrier layer 122. According to some of the embodiments of the present invention, this first electrically conductive barrier layer 122 may be formed as a barrier metal layer containing a metal selected from a group consisting of phosphorus-doped cobalt alloys, boron-doped cobalt alloys, phosphorus-doped nickel alloys, boron-doped nickel alloys, palladium and indium and combinations thereof. A first copper pattern 124 is also formed in the recess 112 using, for example, a copper damascene formation technique that includes planarizing a copper layer for a sufficient duration to define the first copper pattern 124. The step of planarizing a copper layer may include chemically-mechanically polishing the copper layer. As illustrated by FIG. 3A, the first electrically conductive barrier layer 122 extends between the first copper pattern 124 and the first interlayer insulating layer 110. The barrier layer 122 operates to inhibit out-diffusion of copper from the first copper pattern 124 to the surrounding first interlayer insulating layer 110. The barrier layer 122 and the first copper pattern 124 collectively define an electrically conductive pattern 120.

Referring now to FIG. 3B, a second electrically conductive barrier layer 132 is then formed on an upper surface of the first copper pattern 124. This second electrically conductive barrier layer 132, which inhibits out-diffusion of copper from the first copper pattern 124, may be formed selectively on the first copper pattern 124 using an electroless plating technique. The second electrically conductive barrier layer 132 may be formed as a barrier metal layer containing a metal selected from a group consisting of phosphorus-doped cobalt alloys (e.g., Co—W—P alloy), boron-doped cobalt alloys, phosphorus-doped nickel alloys, boron-doped nickel alloys, palladium and indium and combinations thereof. For example, the second electrically conductive barrier layer 132 may be formed as a metal layer selected from a group consisting of: Co—W—P, Co—Sn—P, Co—P, Co—B, Co—Sn—B, Co—W—B, Ni—W—P, Ni—Sn—P, Ni—P, Ni—B, Ni—Sn—B, Ni—W—B, Pd and In. FIG. 3B also illustrates the formation of a catalytic metal layer 134 on the second electrically conductive barrier layer 132 using, for example, an electroless plating technique. According to some embodiments of the invention, the catalytic metal layer 134 may include a material selected from a group consisting of iron, nickel and cobalt and combinations thereof, however, other materials may also be used. FIG. 3B also illustrates the formation of an electrically conductive capping layer 136 on the catalytic metal layer. This capping layer includes a material that is configured to inhibit out-diffusion of oxygen from a subsequently formed interlayer dielectric layer to the catalytic metal layer 134 and also inhibit over-etch damage that may occur to the catalytic metal layer 134 during a subsequent process step(s). The capping layer 136 may contain a material selected from a group consisting of phosphorus-doped cobalt alloys (e.g., Co—W—P alloy), boron-doped cobalt alloys, phosphorus-doped nickel alloys, boron-doped nickel alloys, palladium and indium and combinations thereof, however, other materials may also be used.

Referring now to FIGS. 3C-3D, a second interlayer insulating layer 140 is formed on the first interlayer insulating layer 110. The second interlayer insulating layer 140 may be formed of a dielectric material such as silicon dioxide or a low-k dielectric material such as SiCOH, for example. The second interlayer insulating layer 140 may then be selectively patterned using conventional techniques to define an opening 142 therein that extends through the second interlayer insulating layer 140 and the electrically conductive capping layer 136 and exposes the catalytic metal layer 134. A plurality of carbon nanotubes 144 may then be formed in the opening 142 using the catalytic metal layer 134 to enhance the rate of nanotube formation within the opening 142 (e.g., via opening). These carbon nanotubes 144 may be formed using conventional techniques, such as chemical vapor deposition, plasma-enhanced chemical vapor deposition, atomic layer deposition and plasma-enhanced atomic layer deposition. As illustrated by FIG. 3D, these carbon nanotubes 144 are electrically connected to the first copper pattern 124 by the catalytic metal layer 134 and the second electrically conductive barrier layer 132. The vertical interconnect structure illustrated by FIG. 3D may be completed by forming an electrically conductive pattern 150 that extends on the second interlayer insulating layer 140 and electrically contacts the plurality of carbon nanotubes 144.

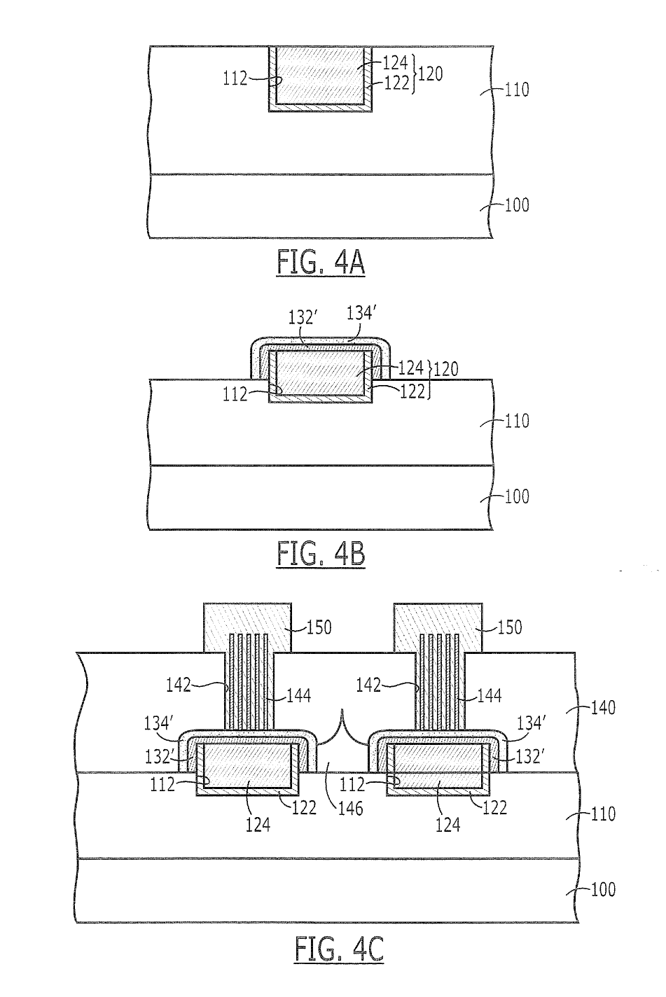

Referring now to FIGS. 4A-4C, methods of forming electrical interconnects according to additional embodiments of the present invention include forming a first interlayer insulating layer 110 on a semiconductor substrate 100 and then forming a recess 112 (e.g., trench pattern) in the first interlayer insulating layer 110 by selectively etching the first interlayer insulating layer 110 using a mask (not shown). As illustrated by FIG. 4A, the first interlayer insulating layer 110 may be formed directly on a primary surface of the semiconductor substrate 100, however, another intervening layer(s) and/or structure(s) (not shown) may be formed between the semiconductor substrate 100 and the first interlayer insulating layer 110. The first interlayer insulating layer 110 may be formed of a dielectric material such as silicon dioxide or a low-k dielectric material such as SiCOH, for example.

A bottom and sidewalls of the recess 112 are then lined with a first electrically conductive barrier layer 122. According to some of the embodiments of the present invention, this first electrically conductive barrier layer 122 may be formed as a barrier metal layer containing a metal selected from a group consisting of phosphorus-doped cobalt alloys, boron-doped cobalt alloys, phosphorus-doped nickel alloys, boron-doped nickel alloys, palladium and indium and combinations thereof. A first copper pattern 124 is also formed in the recess 112 using, for example, a copper damascene formation technique that includes planarizing a copper layer for a sufficient duration to define the first copper pattern 124. The step of planarizing a copper layer may include chemically-mechanically polishing the copper layer.

Referring now to FIG. 4B, a step is performed to selectively etch back the first interlayer insulating layer 110 for a sufficient duration to expose upper sidewalls of the first electrically conductive barrier layer 122. A sequence of plating steps (e.g., electroless plating) are then performed to: (i) plate a second electrically conductive barrier layer 132′ onto the exposed sidewalls of the first electrically conductive barrier layer 122 and an upper surface of the first copper pattern 124, and (ii) plate a catalytic metal layer 134′ onto the second electrically conductive barrier layer 132′, as illustrated.

Referring now to FIG. 4C, the intermediate structure illustrated by FIG. 4B may be replicated multiple times across the semiconductor substrate 100 to yield a plurality of first copper patterns 124 located within side-by-side recesses within the first interlayer insulating layer 110. A second interlayer insulating layer 140 is then deposited onto the first interlayer insulating layer 110, as illustrated, and a plurality of openings 142 are formed within the second interlayer insulating layer 140. As illustrated, in the event the adjacent first copper patterns 124 are sufficiently close, then a void 146 may be advantageously formed within the second interlayer insulating layer 140 as the second interlayer insulating layer is being deposited, at an interface with the first interlayer insulating layer 110. The presence of this void 146 may reduce the effective dielectric constant of the second interlayer insulating layer 140 in regions near the copper patterns 124 and thereby reduce parasitic coupling capacitances between adjacent copper patterns 124, for example. The steps illustrated and described above with respect to FIGS. 1D-1E may then be performed to define the carbon nanotubes 144 within the openings 142 and the electrically conductive patterns 150 on the carbon nanotubes 144, as illustrated by FIG. 4C.

In the drawings and specification, there have been disclosed typical preferred embodiments of the invention and, although specific terms are employed, they are used in a generic and descriptive sense only and not for purposes of limitation, the scope of the invention being set forth in the following claims.

1. An integrated circuit device, comprising:
a first metal region having a first metal therein, on an integrated circuit substrate;
a first electrically conductive barrier layer on a surface of said first metal region, said first electrically conductive barrier layer comprising a material that inhibits outdiffusion of the first metal from said first metal region;
a second metal region having a catalytic metal therein, on said first electrically conductive barrier layer;
an electrically insulating layer on said second metal region, said electrically insulating layer having an opening therein that exposes a portion of said second metal region; and
a plurality of carbon nanotubes that extend in the opening and are electrically coupled to said first metal region by the exposed portion of said second metal region and said first electrically conductive barrier layer.

2. The device of claim 1, wherein the first metal is copper; and wherein said electrically conductive barrier layer comprise at least one of cobalt alloys, nickel alloys, palladium and indium and combinations thereof.

3. The device of claim 2, wherein the catalytic metal is a metal selected from a group consisting of iron, nickel, cobalt, tungsten, yttrium, palladium and platinum.

4. The device of claim 1, further comprising a second electrically conductive barrier layer on said plurality of carbon nanotubes.

5. The device of claim 4, wherein the second electrically conductive barrier layer comprises a metal selected from a group consisting of tantalum, tantalum nitride, tungsten, and tungsten nitride.

6. The device of claim 5, further comprising a copper damascene pattern on the second electrically conductive barrier layer.

7. The device of claim 1, further comprising an electrically conductive capping layer between said second metal region and said electrically insulating layer, said electrically conductive capping layer comprising a material that inhibits outdiffusion of oxygen from said electrically insulating layer to said second metal region.

8. The device of claim 7, wherein said electrically conductive capping layer has an opening therein that is aligned with the opening in said electrically insulating layer.

9. The device of claim 7, wherein said electrically conductive capping layer contacts an upper surface of said second metal region and comprises a metal selected from a group consisting of cobalt alloys, nickel alloys, palladium and indium and combinations thereof.

10. The device of claim 7, wherein said electrically conductive capping layer contacts an upper surface of said second metal region and comprises a metal selected from a group consisting of phosphorusdoped cobalt alloys, borondoped cobalt alloys, phosphorusdoped nickel alloys, borondoped nickel alloys, palladium and indium and combinations thereof.

11. An integrated circuit device, comprising:
a semiconductor substrate;
a first interlayer insulating layer on said semiconductor substrate, said first interlayer insulating layer having a recess therein;
a first copper pattern in the recess in said first interlayer insulating layer;
a first electrically conductive barrier layer lining a bottom and sidewalls of the recess so that the first electrically conductive barrier layer extends between said first copper pattern and the first interlayer insulating layer, said first electrically conductive barrier layer comprising a material that inhibits outdiffusion of copper from said first copper pattern;
a second electrically conductive barrier layer on an upper surface of said first copper pattern, said second electrically conductive barrier layer comprising a material that inhibits outdiffusion of copper from said first copper pattern;
a catalytic metal layer on said second electrically conductive barrier layer;
a second interlayer insulating layer on said catalytic metal layer, said second interlayer insulating layer having an opening therein that exposes a portion of said catalytic metal layer; and
a plurality of carbon nanotubes that extend in the opening and are electrically coupled to said first copper pattern by the exposed portion of said catalytic metal layer and said second electrically conductive barrier layer.

12. The device of claim 11, wherein said second electrically conductive barrier layer comprises a metal selected from a group consisting of phosphorusdoped cobalt alloys, borondoped cobalt alloys, phosphorusdoped nickel alloys, borondoped nickel alloys, palladium and indium and combinations thereof.

13. The device of claim 11, further comprising a capping layer extending between said catalytic metal layer and said second interlayer insulating layer.

14. The device of claim 13, wherein said capping layer comprises a metal selected from a group consisting of phosphorusdoped cobalt alloys, borondoped cobalt alloys, phosphorusdoped nickel alloys, borondoped nickel alloys, palladium and indium and combinations thereof.

15. The device of claim 11, further comprising a capping layer between said catalytic metal layer and said second interlayer insulating layer, said capping layer comprising a material that inhibits outdiffusion of oxygen from said electrically insulating layer to said catalytic metal layer.

16. The device of claim 12, wherein said first electrically conductive barrier layer comprises a metal selected from a group consisting of phosphorusdoped cobalt alloys, borondoped cobalt alloys, phosphorusdoped nickel alloys, borondoped nickel alloys, palladium and indium and combinations thereof.

17. The device of claim 16, wherein the catalytic metal layer comprises at least one of iron, nickel and cobalt and combinations thereof.

18. An integrated circuit device, comprising:
a semiconductor substrate;
a first interlayer insulating layer on said semiconductor substrate, said first interlayer insulating layer having a recess therein;
a copper pattern in the recess in said first interlayer insulating layer;
an electrically conductive barrier layer on an upper surface of said copper pattern, said electrically conductive barrier layer comprising a metal selected from a group consisting of phosphorusdoped cobalt alloys, borondoped cobalt alloys, phosphorusdoped nickel alloys, borondoped nickel alloys, palladium and indium and combinations thereof;
a catalytic metal layer on said electrically conductive barrier layer;
an electrically conductive capping layer on said catalytic metal layer, said electrically conductive capping layer having an upper surface coplanar with an upper surface of said first interlayer insulating layer and comprising a metal selected from a group consisting of phosphorusdoped cobalt alloys, borondoped cobalt alloys, phosphorusdoped nickel alloys, borondoped nickel alloys, palladium and indium and combinations thereof;
a second interlayer insulating layer on the first interlayer insulating layer, said second interlayer insulating layer having an opening therein that is aligned with an opening in said electrically conductive capping layer; and
a plurality of carbon nanotubes that extend through the openings in said second interlayer insulating layer and said electrically conductive capping layer and contact said catalytic metal layer.

19. The device of claim 18, further comprising a copper damascene pattern that extends in said second interlayer insulating layer and is electrically coupled to said plurality of carbon nanotubes.

20.-28. (canceled)
